(19) United States
(12) Patent Application Publication
(10) Pub. No.: US 2015/0058684 A1
(43) Pub. Date: Feb. 26, 2015

(54) TEST METHOD, INFORMATION PROCESSING DEVICE, AND NON-TRANSITORY COMPUTER-READABLE STORAGE MEDIUM

(71) Applicant: FUJITSU LIMITED, Kawasaki-shi (JP)

(72) Inventor: Shinsuke TERANISHI, Yokohama (JP)

(73) Assignee: FUJITSU LIMITED, Kawasaki-shi (JP)

(21) Appl. No.: 14/333,770

(22) Filed: Jul. 17, 2014

(30) Foreign Application Priority Data
Aug. 22, 2013 (JP) 2013-172504

(51) Int. Cl. G11C 29/18; G06F 11/30

(52) U.S. Cl. CPC G11C 29/18; G06F 11/3037
USPC 714/718

(57) ABSTRACT

A test method includes transmitting a plurality of first requests at first time intervals from a first node to a third node with a memory, transmitting a plurality of second requests at the first time intervals from a second node to the third node, after transmitting the plurality of first requests and the plurality of second requests, transmitting a plurality of third requests at the first time intervals from the first node to the third node and transmitting a plurality of fourth requests at the first time intervals from the second node to the third node, and based on data read from the memory for the plurality of first requests and the plurality of second requests, setting times at which the plurality of third requests arrive at the third node so that the plurality of third requests and the plurality of fourth requests arrive at the third node alternately.

### CROSS-REFERENCE TO RELATED APPLICATION

This application is based upon and claims the benefit of priority of the prior Japanese Patent Application No. 2013-172504, filed on Aug. 22, 2013, the entire contents of which are incorporated herein by reference.

### FIELD

The embodiment discussed herein is related to a test method, an information processing apparatus, and a non-transitory computer-readable storage medium.

### BACKGROUND

An information processor, such as a server, has a plurality of nodes, which each include a processor, memory, and a memory control unit that controls access to the memory. In the information processor, the plurality of nodes are coupled to one another through an interconnection, such as a bus. In the information processor, when the memory included in each node is accessed from another node, a conflict of bus access requests or a conflict of memory access requests may occur. As used herein, the conflict of the access requests indicates a state in which a plurality of access requests unable to be processed at the same time are received at a bus arbitration circuit or the memory control unit, or the like. Examples of known techniques to address such a state include adjusting timings of processes for access requests with a memory control unit or a bus arbitration circuit, and outputting a busy signal within a period before completion of a process for the access request that has been received previously. A test for verifying whether or not the memory control unit or the bus arbitration circuit operates as desired in the conflict state of the access requests is referred to as an access request conflict test.

In a known technique of testing a bus conflict in a bus conflict operation test of a system that includes a plurality of bus main devices subject to arbitration and a plurality of bus dependent devices subject to arbitration, which are coupled through a bus, data transfer performed by the plurality of bus main devices is repeated until an instruction to end the test operation is given. Also known is a memory conflict time measurement device, which measures time by which the time it takes for a processor or the like to access memory is delayed because of conflicting with another device. Japanese Laid-open Patent Publication No. 05-020222 and Japanese Laid-open Patent Publication No. 2005-258617 are examples of related art.

### SUMMARY

According to an aspect of the invention, a test method includes transmitting a plurality of first requests sequentially at first time intervals from a first node to a third node with a memory, transmitting a plurality of second requests sequentially at the first time intervals from a second node to the third node, after transmitting the plurality of first requests and transmitting the plurality of second requests, transmitting a plurality of third requests sequentially at the first time intervals from the first node to the third node, after transmitting the plurality of first requests and transmitting the plurality of second requests, transmitting a plurality of fourth requests sequentially at the first time intervals from the second node to the third node, and based on data read from the memory for the plurality of first requests and the plurality of second requests, setting times at which the plurality of third requests arrive at the third node so that the plurality of third requests and the plurality of fourth requests arrive at the third node alternately.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates a hardware configuration of an information processor according to an aspect of an embodiment;

FIG. 2 is a functional block diagram of a processor of a first node according to an aspect of the embodiment;

FIG. 3 is a functional block diagram of a processor of a second node according to an aspect of the embodiment;

FIG. 4 is a functional block diagram of a processor of a third node according to an aspect of the embodiment;

FIGS. 5A and 5B illustrate a description format and description contents of an access request based on an atomic command according to an aspect of the embodiment;

FIG. 6 is a flow chart of operations performed when an access request based on an atomic command according to an aspect of the embodiment is received;

FIGS. 7A and 7B illustrate test programs according to an aspect of the embodiment;

FIGS. 8A and 8B illustrate the contents of access requests based on atomic commands according to an aspect of the embodiment;

FIG. 9 illustrates the arrival timings of access requests and the contents of data in memory according to an aspect of the embodiment;

FIG. 10 illustrates data read for access requests according to an aspect of the embodiment;

FIG. 11 illustrates the arrival timings of access requests and the contents of data in memory according to an aspect of the embodiment;

FIG. 12 illustrates data read for access requests according to an aspect of the embodiment;

FIG. 13 illustrates the arrival timings of access requests and the contents of data in memory according to an aspect of the embodiment;

FIG. 14 illustrates data read for access requests according to an aspect of the embodiment;

FIG. 15 illustrates the arrival timings of access requests according to an aspect of the embodiment;

FIG. 16 illustrates the arrival timings of access requests according to an aspect of the embodiment;

FIG. 17 illustrates the arrival timings of access requests according to an aspect of the embodiment;

FIG. 18 is a flow chart that illustrates operations for adjusting arrival times at a conflict test target device according to an aspect of the embodiment;

FIG. 19 is a flow chart that illustrates operations for acquiring an arrival time adjustment value according to an aspect of the embodiment; and

FIG. 20 is a flow chart that illustrates operations for conducting an access request conflict test using an arrival time adjustment value according to an aspect of the embodiment.

### DESCRIPTION OF EMBODIMENT

In order to conduct an access request conflict test, it is desired to cause a state in which a plurality of access requests conflict in a memory control unit in a node that receives the access requests. However, even when two nodes that transmit access requests transmit respective access requests to a node on the reception side while controlling timings, the times at which the access requests arrive at the node on the reception side may differ. For example, since a difference occurs in the transmission speed dependent on the length of wiring that couples the two nodes on the transmission side of the access requests and the node on the reception side of the access requests, the parasitic resistance, or the like, access latencies may differ. When the plurality of access requests arrive at the node on the reception side at different times and no conflict state is caused, it is impossible to conduct the access request conflict test properly.

The present embodiment is aimed at providing a method that enables an access request conflict test to be conducted properly even when there is a difference in the transmission speed in the wiring that couples a plurality of nodes that issue access requests and a node that receives the access requests.

Examples of an access request to a node used in the present embodiment include a request based on an atomic command. The atomic command is a command that combines a plurality of operations as an integrated unit unable to be divided and the plurality of operations are regarded as one operation when viewed from another part of a system. For example, a series of operations for reading data from memory included in a node, processing the read data, and writing data in the memory may be performed as an integrated procedure.

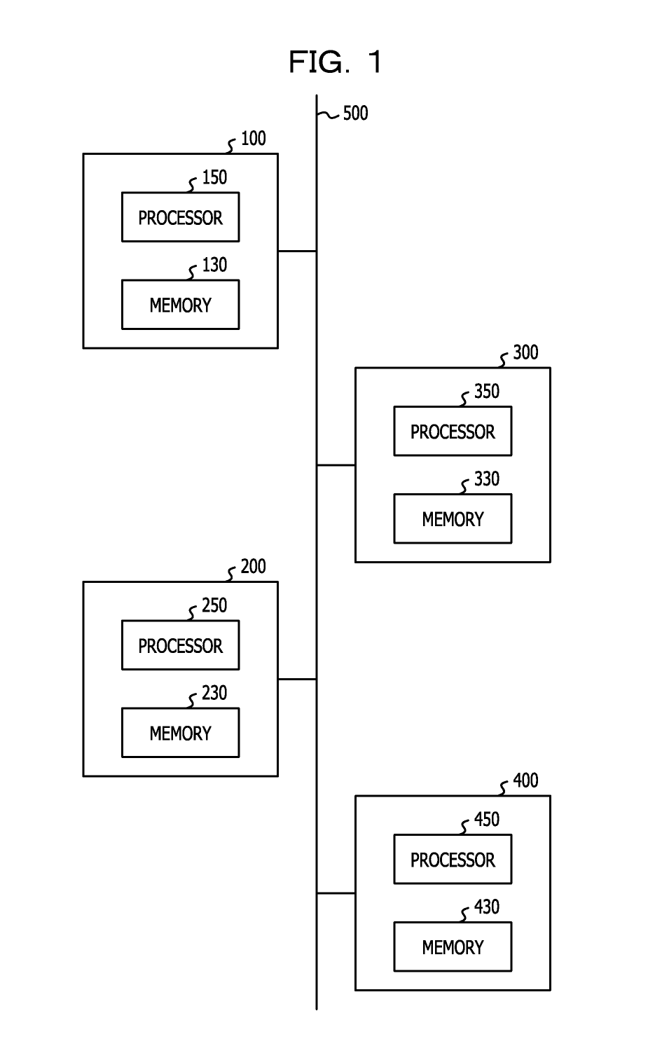

FIG. 1 is a diagram that illustrates a hardware configuration of an information processor according to the embodiment. In FIG. 1, a first node 100, a second node 200, a third node 300, and a management device 400 are coupled to a bus 500. The first node 100 includes a processor 150 and memory 130. A test program that contains a plurality of atomic commands is stored in the memory 130. When the plurality of atomic commands contained in the test program are executed by the processor 150, a plurality of access requests are transmitted to the third node 300 through the bus 500. The second node 200 includes a processor 250 and memory 230. A test program that contains a plurality of atomic commands is stored in the memory 230. When the plurality of atomic commands contained in the test program are executed by the processor 250, a plurality of access requests are transmitted to the third node 300 through the bus 500.

The third node 300 includes a processor 350 and memory 330. The processor 350 controls writing data in the memory 330 or reading data from the memory 330 when there are access requests from the first node 100 or the second node 200 to the memory 330. On receiving the access requests based on the atomic commands from the first node 100 or the second node 200, the processor 350 locks the memory 330 until the operations for the access requests end. When the processor 350 fails to lock the memory 330 properly for the access requests based on the atomic commands, the processor 350 outputs a lock error signal. The management device 400 includes a processor 450 and memory 430, and controls operations of an access request conflict test. Further, the management device 400 receives the lock error signal output from the third node 300. For example, the processors 150, 250, 350, and 450 are electronic circuits, such as central processing unit (CPU) chips, and the memory 130, the memory 230, the memory 330, and the memory 430 are electronic circuits, such as dynamic random access memory (DRAM) chips.

It is assumed in the present embodiment that a plurality of access requests based on a plurality of atomic commands are issued from each of the first node 100 and the second node 200 and the third node 300 receives the access requests. The first node 100 and the second node 200 are referred to as conflict test devices and the third node 300 is referred to as a conflict test target device.

In the present embodiment, even when the transmission speed of the wiring that couples the first node 100 and the third node 300 is different from the transmission speed of wiring that couples the second node 200 and the third node 300, approximate differences among the times at which the access requests arrive at the third node 300 may be detected. First, a plurality of access requests based on atomic commands, which are contrary to each other, are issued from each of the first node 100 and the second node 200. The times at which the plurality of access requests issued from the first node 100 or the second node 200 arrive at the third node 300 are adjusted so that the access requests based on the atomic commands, which are contrary to each other, arrive at the third node 300 alternately. After adjusting the arrival times, the issue intervals of at least one of the plurality of access requests issued from the first node 100 and the plurality of access requests issued from the second node 200 are adjusted to conduct an access request conflict test. The contrary relation is described in detail below.

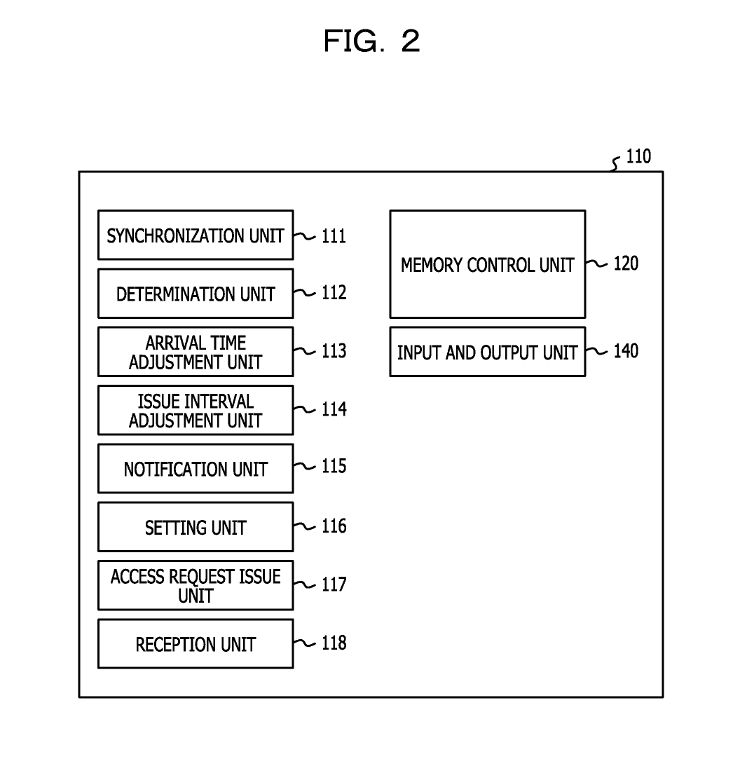

FIG. 2 is a functional block diagram of the processor 150 of the first node 100. The processor 150 operates as a processor that includes functions illustrated in FIG. 2 by executing processes based on a given program stored in the memory 130, the memory of another node, or common memory coupled to the bus 500. The processor 150 functions as a synchronization unit 111, which causes the issue timings of the access requests to match between the nodes, a determination unit 112, which performs each kind of determination, an arrival time adjustment unit 113, which adjusts the issue timing of an access request and adjusts the time at which the issued access request arrives at the issue destination node, an issue interval adjustment unit 114, which adjusts the issue intervals of access requests issued successively, a notification unit 115, which performs each kind of notification for another node, a setting unit 116, which sets the first node 100 as a master node or a slave node in an access request conflict test, an access request issue unit 117, which issues an access request, a reception unit 118, which receives each kind of notification or each kind of data from another node, a memory control unit 120, which controls the memory 130, and an input and output unit 140, which communicates with the bus 500. It is not desired that all the above-described functions be implemented in the processor 150. For example, the memory control unit 120 may be an electronic circuit different from the processor 150. The input and output unit 140 may also be an electronic circuit different from the processor 150.

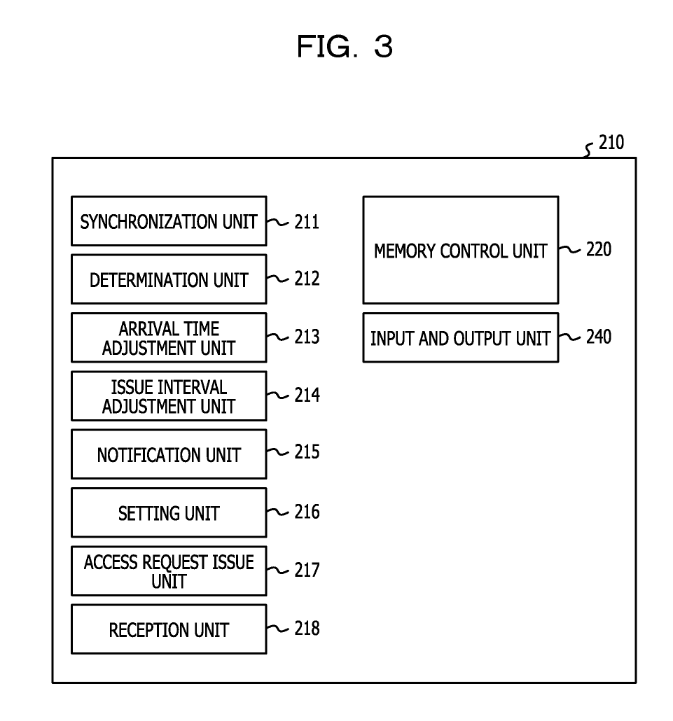

FIG. 3 is a functional block diagram of the processor 250 of the second node 200. The processor 250 operates as a processor that includes functions illustrated in FIG. 3 by executing processes based on a given program stored in the memory 230, the memory of another node, or the common memory coupled to the bus 500. The processor 250 functions as a synchronization unit 211, which causes the issue timings of the access requests to match between the nodes, a determination unit 212, which performs each kind of determination, an arrival time adjustment unit 213, which adjusts the issue timing of an access request and adjusts the time at which the issued access request arrives at the issue destination node, an issue interval adjustment unit 214, which adjusts the issue intervals of access requests issued successively, a notification unit 215, which performs each kind of notification for another node, a setting unit 216, which sets the second node 200 as a master node or a slave node in an access request conflict test, an access request issue unit 217, which issues an access request, a reception unit 218, which receives each kind of notification or each kind of data from another node, a memory control unit 220, which controls the memory 230, and an input and output unit 240, which communicates with the bus 500. It is not desired that all the above-described functions be implemented in the processor 250. For example, the memory control unit 220 may be an electronic circuit different from the processor 250. The input and output unit 240 may also be an electronic circuit different from the processor 250.

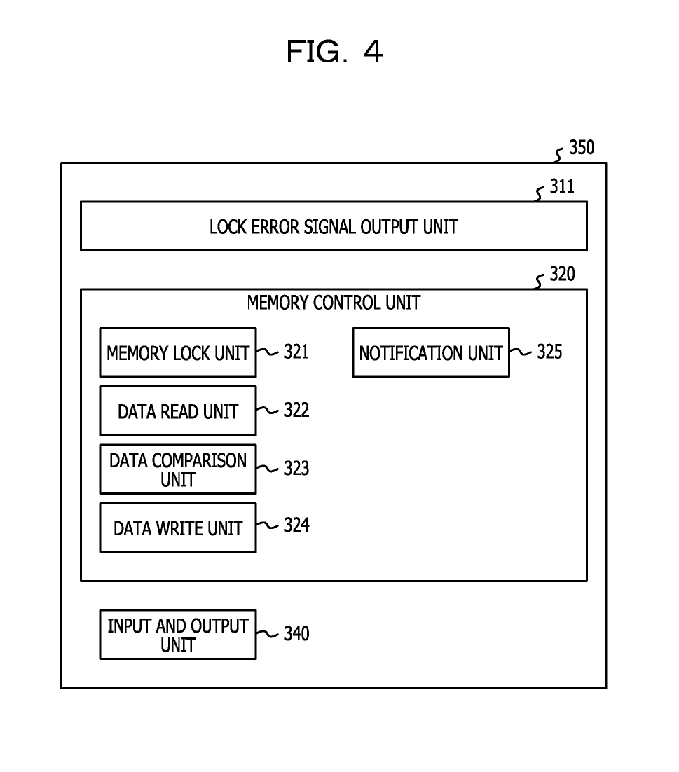

FIG. 4 is a functional block diagram of the processor 350 of the third node 300. The processor 350 operates as a processor that includes functions illustrated in FIG. 4 by executing processes based on a given program stored in the memory 330, the memory of another node, or the common memory coupled to the bus 500. The processor 350 includes a lock error signal output unit 311, which outputs a lock error signal, a memory control unit 320, which controls the memory 330, and an input and output unit 340, which communicates with the bus 500. The memory control unit 320 functions as a memory lock unit 321, which locks the memory 330 when an access request is received, a data read unit 322, which reads data from the memory 330, a data comparison unit 323, which compares the read data with comparison data, a data write unit 324, which writes storage data in the memory 330, and a notification unit 325, which notifies another node of the data read from the memory 330. It is not desired that all the above-described functions be implemented in the processor 350. For example, the memory control unit 320 may be an electronic circuit different from the processor 350. The input and output unit 340 may also be an electronic circuit different from the processor 350.

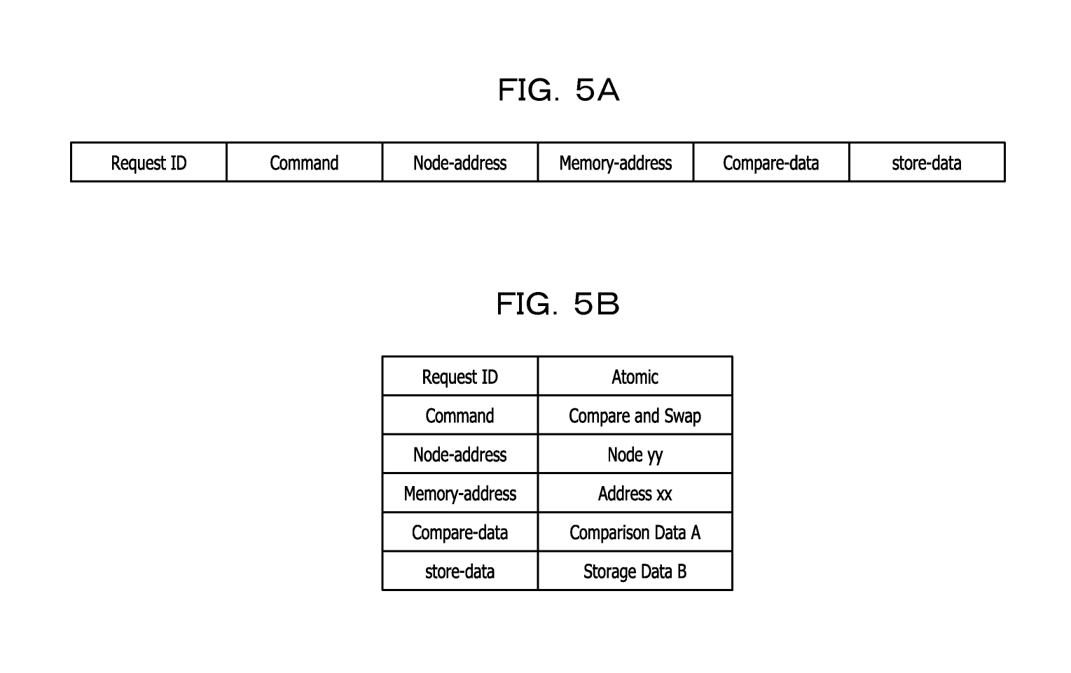

FIG. 5A illustrates a description format of an access request and FIG. 5B illustrates an example of description contents. In the example in FIG. 5A, the description format includes “Request ID” that indicates the type of the access request, “Command” that indicates the contents of the request, “Node-address” that indicates the transmission destination node of the request, “Memory-address” that indicates the address of the target memory, “Compare-data” that indicates comparison data for comparison with the data read from the memory, and “store-data” that indicates data to be written in the memory. In FIG. 5B, “Atomic” described as “Request ID” indicates that the request is an access request based on an atomic command. Further, “Compare and Swap” described as “Command” serves to provide instructions on an operation of reading data stored at the addresses designated as “Node-address” and “Memory-address”, an operation of comparing the read data with comparison data A described as “Compare-data”, and an operation of writing storage data B described as “store-data” in the memory when both values match as a result of the comparison. That is, a series of operations of reading data, comparing data, and writing data are performed as an integrated procedure.

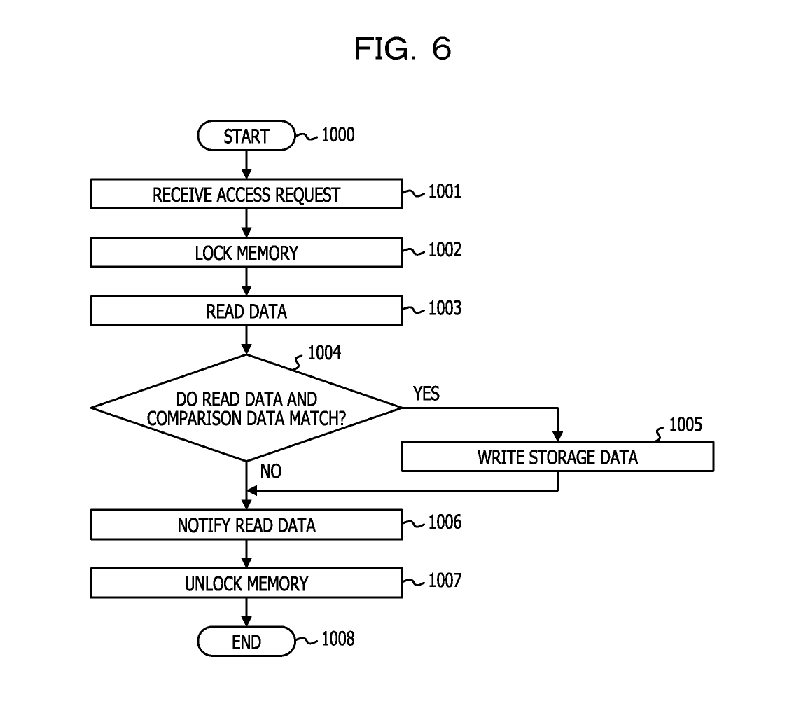

FIG. 6 is a flow chart that illustrates operations performed by the processor 350 when, for example, the third node 300 receives an access request of “Compare and Swap”, which start in operation 1000. In operation 1001, the third node 300 receives an access request from an issue source node of the access request. In operation 1002, the memory lock unit 321 locks the memory 330 in accordance with “Request ID” indicating “Atomic” and disables accesses of other requests. In operation 1003, the data read unit 322 reads the data stored at the address of the memory, which is specified by “Memory-address”. In operation 1004, the data comparison unit 323 compares the comparison data A described as “Compare-data” of the access request with the data that has been read in operation 1003. When the read data and the comparison data match, in operation 1005, the data write unit 324 writes the storage data B described as “store-data” of the access request in the memory 330 and the process proceeds to operation 1006. When the read data and the comparison data do not match, in operation 1006, the notification unit 325 transmits the read data to the issue source node of the access request. In operation 1007, the memory lock unit 321 unlocks the memory 330 and the process ends in operation 1008.

Described now is a method of estimating an approximate amount of time by which the times at which the access requests issued from the first node 100 and the second node 200 arrive at the third node 300 differ using such an access request of “Compare and Swap” based on the atomic command.

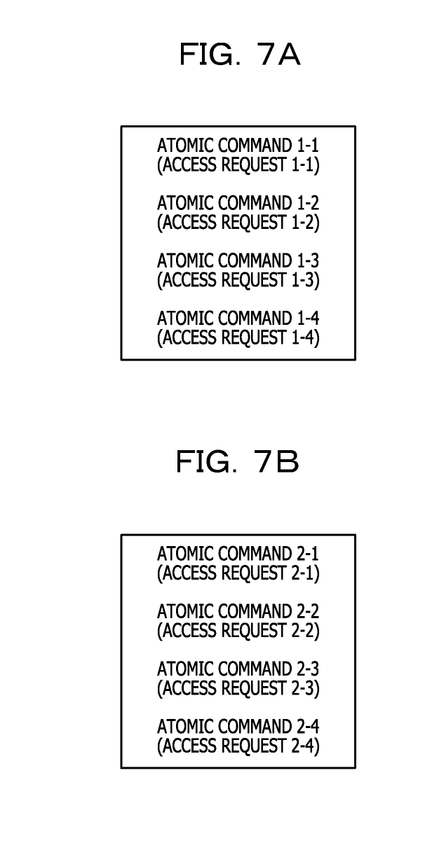

FIGS. 7A and 7B illustrate test programs used in the present embodiment. FIG. 7A illustrates an example of the test program stored in the memory 130 of the first node 100 while FIG. 7B illustrates an example of the test program stored in the memory 230 of the second node 200. As illustrated in FIG. 7A, the test program stored in the memory 130 of the first node 100 includes atomic commands 1-1 to 1-4. When the processor 150 executes the test program, access requests 1-1 to 1-4 based on the atomic commands 1-1 to 1-4 are successively issued. As illustrated in FIG. 7B, the test program stored in the memory 230 of the second node 200 includes atomic commands 2-1 to 2-4. When the processor 250 executes the test program, access requests 2-1 to 2-4 based on the atomic commands 2-1 to 2-4 are successively issued. Although, in the present embodiment, each of FIGS. 7A and 7B illustrates the test program that includes four atomic commands, the number of atomic commands included in a test program is not limited to four. It is not desired for the test programs to be stored in the memory 130 of the first node 100 and the memory 230 of the second node 200 on every occasion, and it is allowed to download and use a program stored in memory of another node or common memory as each of the test programs.

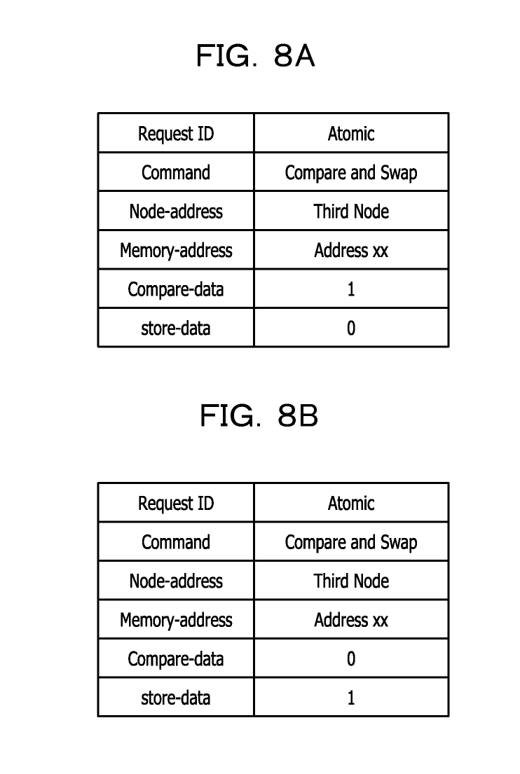

FIGS. 8A and 8B illustrate the contents of access requests based on atomic commands according to the embodiment. FIG. 8A illustrates the contents of the access requests 1-1 to 1-4 while FIG. 8B illustrates the contents of the access requests 2-1 to 2-4. In the contents of each of the access requests 1-1 to 1-4, “Request ID” indicates “Atomic”, “Command” indicates “Compare and Swap”, “Node-address” indicates the third node 300, “Memory-address” indicates xx, “Compare-data” indicates “1”, and “store-data” indicates “0”. In the contents of each of the access requests 2-1 to 2-4, “Request ID” indicates “Atomic”, “Command” indicates “Compare and Swap”, “Node-address” indicates the third node 300, “Memory-address” indicates xx, “Compare-data” indicates “0”, and “store-data” indicates “1”.

The access requests 1-1 to 1-4 cause “0” to be written in the memory 330 when the data read from the memory 330 indicates “1”. The access requests 2-1 to 2-4 cause “1” to be written in the memory 330 when the data read from the memory 330 indicates “0”. In this manner, when the logical values that the comparison data and the written data indicate in the commands are contrary to each other, such requests are herein referred to as the requests in a contrary relation.

An initial value “1” is stored in the memory 330 of the third node 300 prior to issuing the access requests 1-1 to 1-4 from the first node 100 and issuing the access requests 2-1 to 2-4 from the second node 200. Certain data is mutually transmitted between the first node 100 and the second node 200 and a synchronization operation is repeated for synchronization until the data of both may be confirmed. After that, a plurality of access requests are successively issued from each of the first node 100 and the second node 200 to the third node 300. The four access requests 1-1 to 1-4 are transmitted from the first node 100 to the third node 300 at given issue intervals. The four access requests 2-1 to 2-4 are transmitted from the second node 200 to the third node 300 at the same issue intervals as the intervals at which the access requests 1-1 to 1-4 are issued.

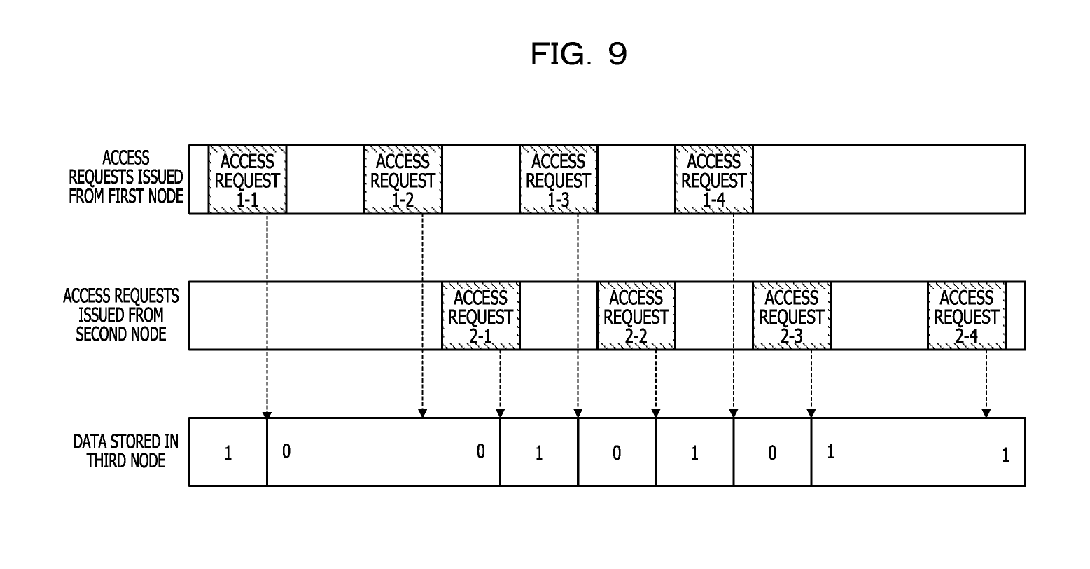

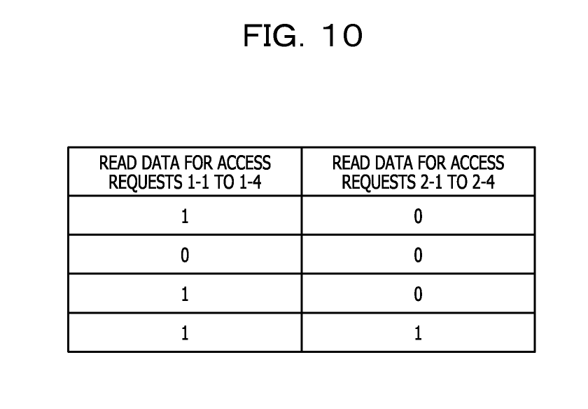

FIG. 9 illustrates the timings at which the access requests 1-1 to 1-4 and the access requests 2-1 to 2-4 arrive at the third node 300 and the contents of data in the memory 330 of the third node 300. In FIG. 9, the upper row indicates the timings at which the access requests 1-1 to 1-4 arrive at the third node 300, the middle row indicates the timings at which the access requests 2-1 to 2-4 arrive at the third node 300, and the lower row indicates changes in the data in the memory 330 of the third node 300. FIG. 10 illustrates the data read from the memory 330 for the plurality of access requests. The left column of FIG. 10 indicates the sequence of data read from the memory 330 for the access requests 1-1 to 1-4 and transmitted to the first node 100. The right column of FIG. 10 indicates the sequence of data read from the memory 330 for the access requests 2-1 to 2-4 and transmitted to the second node 200.

FIG. 9 illustrates an example in which the signal transmission speed of the wiring that couples the second node 200 and the third node 300 is lower than the signal transmission speed of the wiring that couples the first node 100 and the third node 300. In this example, the first access request 2-1 transmitted from the second node 200 arrives later than the first access request 1-1 transmitted from the first node 100. Further, in this example, the first access request 2-1 issued from the second node 200 arrives at the third node 300 at a timing between the access request 1-2 issued secondly from the first node 100 and the access request 1-3 issued thirdly from the first node 100.

The operations of the third node 300 that receives the access requests 1-1 to 1-4 and the access requests 2-1 to 2-4 at such timings are described below. First, when the access request 1-1 arrives at the third node 300, the processor 350 reads data stored in the memory 330, which is the initial value “1” in this case. After that, the read data indicating “1” is compared with the comparison data of the access request 1-1, which indicates “1”. Since the data both indicate “1” and match each other, the storage data of the access request 1-1, which indicates “0”, is written in the memory 330 of the third node 300 and the read data “1” is transmitted to the first node 100. Accordingly, the first data in the left column of FIG. 10 indicates “1”.

After that, as illustrated in FIG. 9, the access request 1-2 arrives at the third node 300. The processor 350 reads “0”, which is the data stored in the memory 330 at this timing, and compares the read data with the comparison data of the access request 1-2, which indicates “1”. Since both data differ this time, “0” is maintained without rewriting the data in the memory 330 and the read data, which indicates “0”, is transmitted to the first node 100. Accordingly, the second data in the left column of FIG. 10 indicates “0”.

After that, as illustrated in FIG. 9, the access request 2-1 issued from the second node 200 arrives at the third node 300. The processor 350 reads the data stored in the memory 330, which indicates “0”, and compares the read data with the comparison data of the access request 2-1, which indicates “0”. Since the logical values of both data are identical, the read data “0” is transmitted to the second node 200, and the storage data “1” of the access request 2-1 is written in the memory 330 of the third node 300. Accordingly, the first data in the right column of FIG. 10 indicates “0”.

As illustrated in FIG. 9, the access requests 1-3 and 1-4 transmitted from the first node 100 and the access requests 2-2 and 2-3 transmitted from the second node 200 are input to the third node 300 alternately. As a result, the read data “1” is successively transmitted to the first node 100 and the read data “0” is successively transmitted to the second node 200.

The access request transmitted lastly from the first node 100 is the access request 1-4 and after the access request 1-4, the access requests 2-3 and 2-4 transmitted from the second node 200 are successively input to the third node 300. Because of the access request 2-3, the data of the memory 330 indicates “1”. Thus, when the access request 2-4 is input, the read data “1” and the comparison data “0” do not match and the data in the memory 330 of the third node 300 is maintained to indicate “1” without being rewritten. The read data “1” is transmitted to the second node 200.

An expected value of the read data is described below. When the comparison data indicates “1” and the storage data indicates “0” for an access request, “1” is referred to as the expected value of the read data, and when the comparison data indicates “0” and the storage data indicates “1” for the access request, “0” is referred to as the expected value of the read data. That is, the expected value of the read data for the first node 100 from which the access requests 1-1 to 1-4 are issued is “1”, and the expected value of the read data for the second node 200 from which the access requests 2-1 to 2-4 are issued is “0”.

Referring to FIG. 10, a method of finding out how different the times at which the access requests 1-1 to 1-4 and the access requests 2-1 to 2-4 arrive at the third node 300 are from the read data. The first value of the read data for the access requests 1-1 to 1-4 issued from the first node 100 is “1”, which equals the expected value. In contrast, the second value of the read data is “0”, which is a value different from the expected value. The first value of the read data for the access requests 2-1 to 2-4 issued from the second node 200 is “0”, which equals the expected value. The second value is also “0”, which equals the expected value. In such a case, it may be found out that the access requests issued from the node corresponding to the read data in which the top two pieces of data include a value different from the expected value arrive at the third node 300 earlier than the access requests issued from the node corresponding to the read data in which both the top two pieces of data equal the expected value. It may also be found out from the contents of the read data that the second access request 1-2 issued from the first node 100 arrives earlier than the first access request 2-1 issued from the second node 200. Since the third data in the read data sequence of the first node 100 indicates “1”, which equals the expected value, it may be found out that the access request 2-1 arrives between the access request 1-2 and the access request 1-3.

In this manner, the read data for the access requests enables it to identify which one of the access requests issued from the first node 100 and the access requests issued from the second node 200 arrives at the third node 300 later and how different the arrival timings are, in other words, which one of signal transmission passages has the larger transmission delay and how large the transmission delay is.

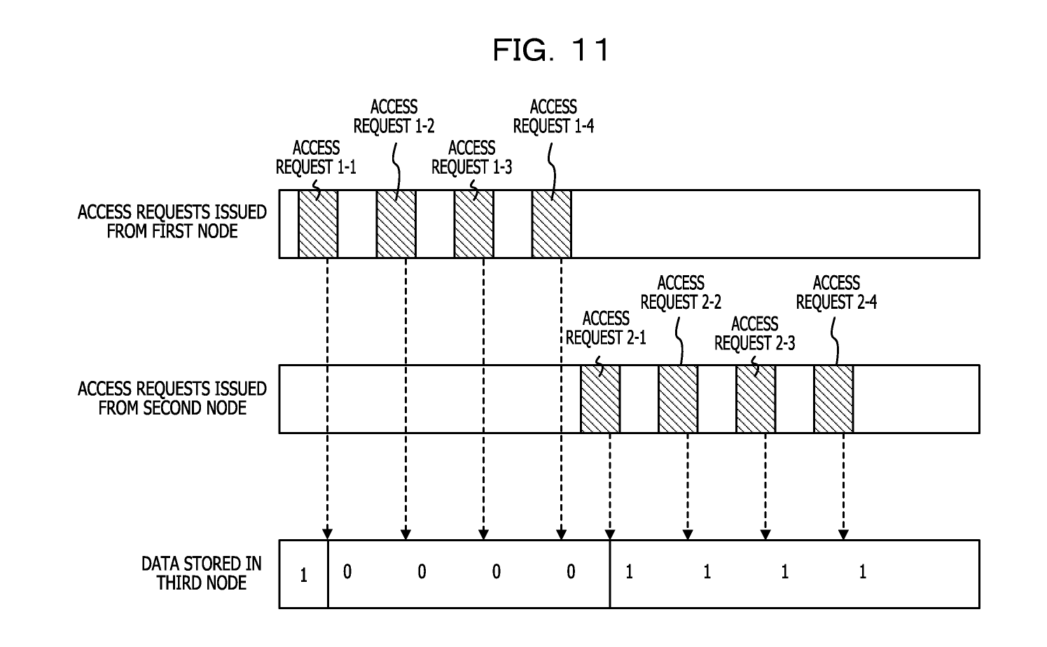

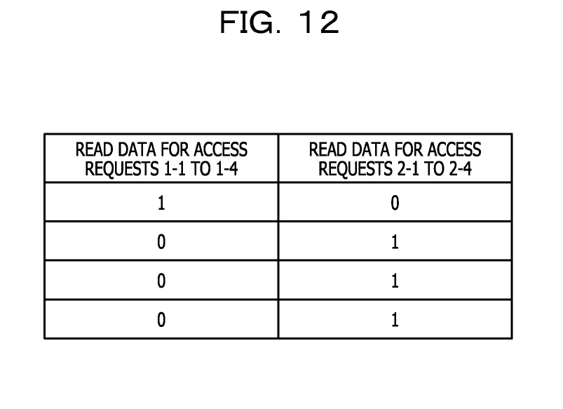

FIG. 11 illustrates another example of the timings at which the access requests 1-1 to 1-4 and the access requests 2-1 to 2-4 arrive at the third node 300 and the contents of the data in the memory 330 of the third node 300. FIG. 12 illustrates the data read from the memory 330 for the access requests 1-1 to 1-4 and the access requests 2-1 to 2-4 in the case of FIG. 11. FIG. 11 illustrates a case in which the first access request 2-1 issued from the second node 200 arrives at the third node 300 later than the last access request 1-4 issued from the first node 100. In this case, as illustrated in FIG. 12, the top two pieces of data in the read data corresponding to the first node 100 include “1”, which is the expected value, and “0”, which is a value different from the expected value, and the top two pieces of data in the read data corresponding to the second node 200 also include “0”, which is the expected value, and “1”, which is a value different from the expected value. That is, even when the top two pieces of data in the read data are compared, it is impossible to determine which one of the access requests issued from the first node 100 and the access requests issued from the second node 200 arrives at the third node 300 first. In such a case, the read data is acquired again by increasing the number of access requests based on the atomic commands, which are successively issued from the first node 100 and the second node 200. For example, the number of access requests that are based on the atomic commands and are successively issued from the first node 100 and the second node 200 is increased by eight each. Thus, it may be avoided that the first access request issued from the second node 200 arrives at the third node 300 later than the last access request issued from the first node and the determination based on the values of the top two pieces of data in the read data may be possible.

The method of detecting an approximate degree of the differences in the arrival times at the third node 300 using the access requests based on the atomic commands, which are in the contrary relation as described above. Now described is a method of causing the access requests 1-1 to 1-4 and the access requests 2-1 to 2-4 to be alternately input to the third node 300 by adjusting the arrival times of the access requests 1-1 to 1-4 that arrive at the third node 300 earlier. Examples of the method of adjusting the times at which the access requests 1-1 to 1-4 arrive at the third node 300 include a method of delaying the timings at which the access requests 1-1 to 1-4 are issued in the processor 150 of the first node 100 by a certain length of time, a method of causing a delay of a certain length of time in the processor 350 of the third node 300 that receives the access requests 1-1 to 1-4, and a method of adjusting delay time by providing a variable delay circuit between the input and output unit 140 of the first node 100 and the input and output unit 340 of the third node 300. While a process for “the adjustment of the arrival times”, as used herein, may be involved in all the above-described methods, the method of adjusting the issue timings of the access requests 1-1 to 1-4 in the processor 150 of the first node 100 is described below as an example.

As described above, it may be found out from the results of FIG. 10 that the access request 1-1 issued from the first node 100 arrives at the third node 300 earlier than the access request 2-1. Thus, a given value is set for the arrival time adjustment unit 113 and the timings at which the access requests 1-1 to 1-4 are issued from the first node 100 are delayed by a certain length of time, and then the timings at which the access requests 1-1 to 1-4 arrive at the third node 300 are adjusted so as to be delayed by a certain length of time. In this case, no adjustment is performed for the arrival time adjustment unit 213 of the second node 200. After the data indicating “1” is stored in the memory 330 of the third node 300 as an initial value and the synchronization unit 111 of the first node 100 and the synchronization unit 211 of the second node 200 perform synchronization, the access requests 1-1 to 1-4 and the access requests 2-1 to 2-4 are issued. Then, it is checked whether or not both of the top two pieces of data in the read data for the access requests 1-1 to 1-4 indicate “1”, which equals the expected value, and whether or not both of the top two pieces of data in the read data for the access requests 2-1 to 2-4 indicate “0”, which equals the other expected value. When the read data remains identical to the contents illustrated in FIG. 10, the delay time set for the arrival time adjustment unit 113 is increased, and the access requests 1-1 to 1-4 and the access requests 2-1 to 2-4 are issued again. These operations are repeated until the top two pieces of data in the read data for the access requests 1-1 to 1-4 indicate “1” and the top two pieces of data in the read data for the access requests 2-1 to 2-4 indicate “0”

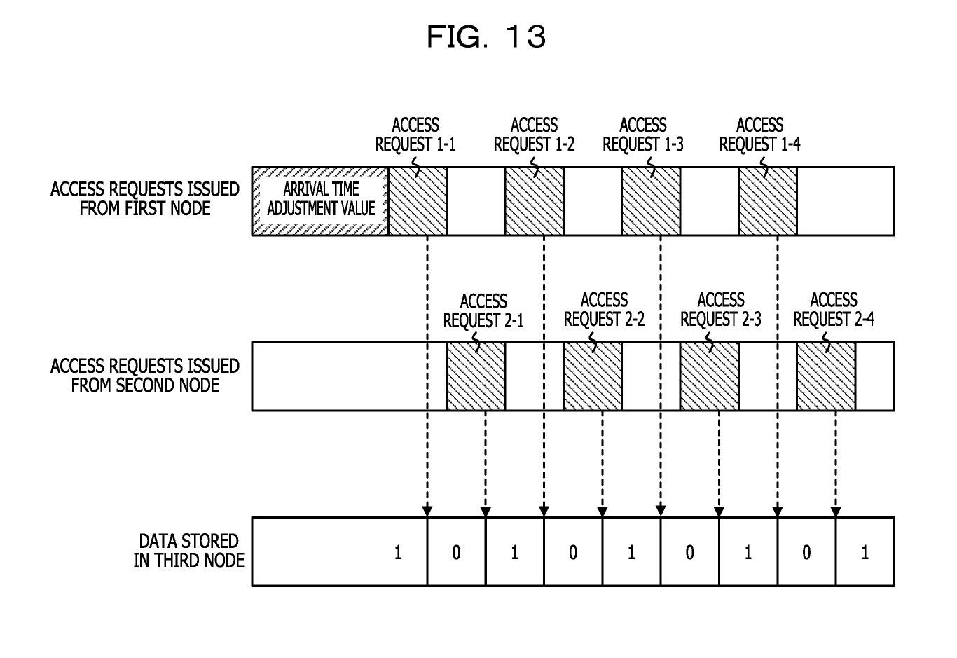

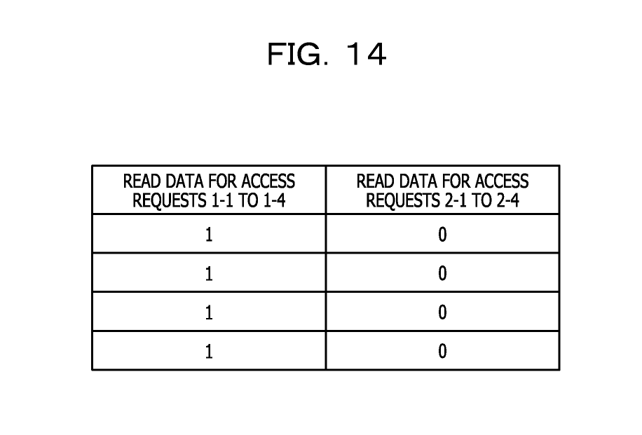

FIG. 13 illustrates the timings at which the access requests 1-1 to 1-4 and the access requests 2-1 to 2-4 arrive at the third node 300, and the changes in the data of the memory 330. FIG. 14 illustrates sequences of the read data for the access requests 1-1 to 1-4 and the access requests 2-1 to 2-4 in the state of FIG. 13. In FIG. 13, the times at which the access requests 1-1 to 1-4 issued from the first node 100 arrive at the third node 300 are adjusted so as to be delayed by a certain length of time, and the access requests 1-1 to 1-4 and the access requests 2-1 to 2-4 arrive at the third node 300 alternately. In this state, as illustrated in FIG. 14, both the top two pieces of data in the read data for the access requests 1-1 to 1-4 indicate “1”, which equals the expected value, and both the top two pieces of data in the read data for the access requests 2-1 to 2-4 indicate “0”, which equals the other expected value. That is, the access requests 1-1 to 1-4 and the access requests 2-1 to 2-4 may be caused to arrive at the third node 300 alternately by adjusting the arrival time adjustment unit 113 so that the top two pieces of data in both of the read data for the access requests issued from the two nodes indicate the respective expected values. An arrival time adjustment value of the arrival time adjustment unit 113 in this state is stored in, for example, the memory 130 of the first node 100. In the present embodiment, it is not necessarily desired to store the arrival time adjustment value in the memory 130, and the arrival time adjustment value may be retained in, for example, the memory 430 of the management device 400.

Now, a method of conducting an access request conflict test using the acquired arrival time adjustment value is described. First, the acquired arrival time adjustment value is set for the arrival time adjustment unit 113, and “1” is set for the memory 330 of the third node 300 as an initial value. After synchronization between the first node 10 and the second node 200, the access requests 1-1 to 1-4 and the access requests 2-1 to 2-4 are successively transmitted from the first node 100 and the second node 200 to the third node 300, respectively. The first access request conflict test is conducted by the processor 450 of the management device 400 detecting whether or not a lock error signal is transmitted from the memory control unit 320 of the third node 300. The read data from the memory 330 for the access requests is stored in the first node 100 and the second node 200 so as to detect when the test ends.

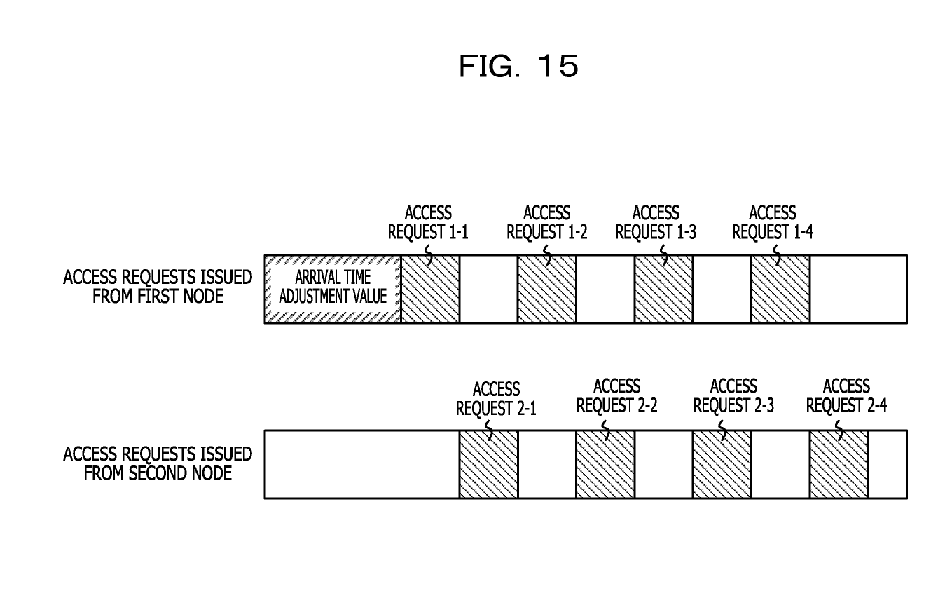

FIG. 15 illustrates the timings at which the access requests 1-1 to 1-4 and the access requests 2-1 to 2-4 arrive at the third node 300 in the above-described first access request conflict test. The access requests 1-1 to 1-4 and the access requests 2-1 to 2-4 may be caused to arrive at the third node 300 alternately as illustrated in FIG. 15 by setting a suitable arrival time adjustment value for the arrival time adjustment unit 113. However, whether or not a conflict state of access requests occurs depends on time desired for the third node 300 to complete the operations for each access request, the issue intervals of the plurality of access requests, and the degree of differences in the arrival times of the access requests 1-1 to 1-4 and the access requests 2-1 to 2-4. Thus, conducting the above-described first test only may be insufficient to cause a conflict state or to end an atomic conflict test.

In view of the above, an access request conflict test conducted using the issue interval adjustment unit 114 and the issue interval adjustment unit 214 illustrated in the functional block diagrams in FIGS. 2 and 3, respectively, is now described. The issue interval adjustment units 114 and 214 include functions of changing the issue intervals of a plurality of sequences of access requests that are successively issued. Described below is an example to conduct an access request conflict test in which the issue intervals of the access requests 1-1 to 1-4 are adjusted in the issue interval adjustment unit 114 of the first node 100.

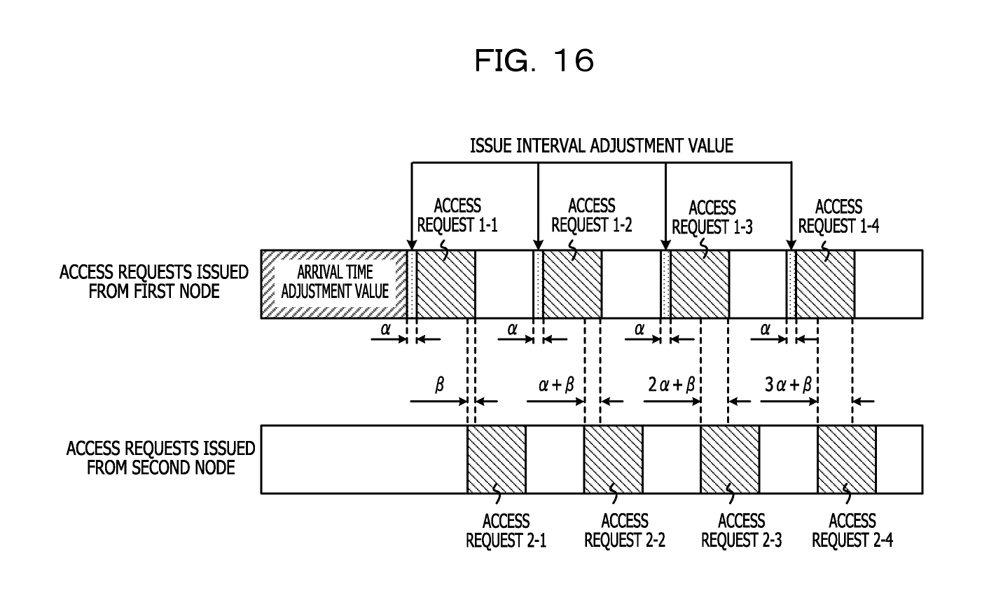

FIG. 16 illustrates the timings at which the access requests 1-1 to 1-4 and the access requests 2-1 to 2-4 arrive at the third node 300 in a re-conducted test in which the issue intervals of the access requests 1-1 to 1-4 are increased by time α compared to the issue intervals of the access requests 2-1 to 2-4 by adjusting the issue interval adjustment unit 114.

While the access requests 1-1 to 1-4 and the access requests 2-1 to 2-4 cause no conflict in the example illustrated in FIG. 15, FIG. 16 illustrates an example of a state in which the access request 2-1 arrives before the operations for the access request 1-1 are completed in the third node 300 because the issue intervals of the access requests 1-1 to 1-4 are increased by time α, that is, a situation in which a conflict state is occurring. Herein, β represents the overlapping time of the access request 1-1 and the access request 2-1. When the memory control unit 320 fails to lock the memory 330 properly, the lock error signal output unit 311 transmits a lock error signal to the management device 400. After that, since the issue interval between the access request 1-1 and the access request 1-2 is increased by time α and the time at which the access request 1-2 arrives at the third node 300 is further shifted later by α, the overlapping time of the access request 1-2 and the access request 2-2 amounts to α+β. Similarly, the overlapping time of the access request 1-3 and the access request 2-3 amounts to 2α+β. Further, the overlapping time of the access request 1-4 and the access request 2-4 amounts to 3α+β. In this manner, a plurality of kinds of overlapping time between the access requests 1-1 to 1-4 and the access requests 2-1 to 2-4 may be generated by setting a certain value for the issue interval adjustment unit 114.

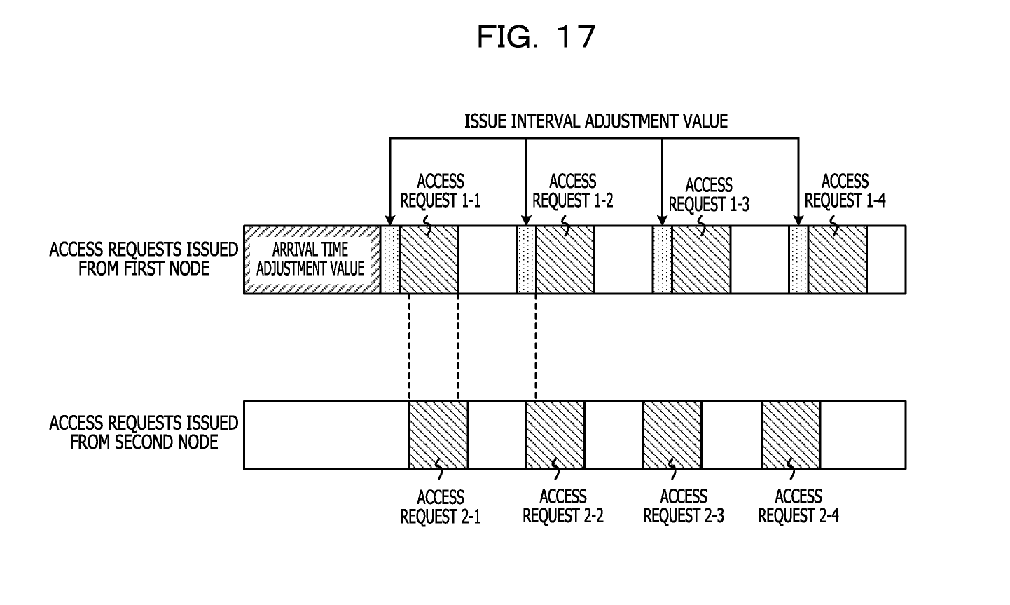

FIG. 17 illustrates the timings at which the access requests 1-1 to 1-4 and the access requests 2-1 to 2-4 arrive at the third node 300 when a test is conducted again by further increasing the issue intervals of the access requests 1-1 to 1-4. In FIG. 17, the access request 1-1 arrives at the third node 300 earlier than the access request 2-1. However, the access request 1-3 arrives at the third node 300 later than the access request 2-3. That is, FIG. 17 illustrates a state in which the access requests 1-1 to 1-4 and the access requests 2-1 to 2-4 do not arrive at the third node 300 alternately. Accordingly, the read data for the access request 2-3 indicates “1”, which is a value different from the expected value. When the determination unit 212 of the second node 200 identifies the read data as including a value different from the expected value, the determination unit 212 determines that various kinds of overlapping may have been generated sufficiently among the access requests issued from the first node 100 and the access requests issued from the second node 200. After that, the notification unit 215 generates a test end signal for the first node 100. On receiving the test end signal, the first node 100 ends the access request conflict test.

Although the present embodiment describes an example of increasing the issue intervals of the first node 100 in which the arrival time adjustment unit 113 undergoes the setting, the adjustment may be performed by increasing the issue intervals of the second node 200. The issue intervals may be decreased in adjusting the issue intervals. In addition, both the issue intervals of the first node 100 and the issue intervals of the second node 200 may be adjusted.

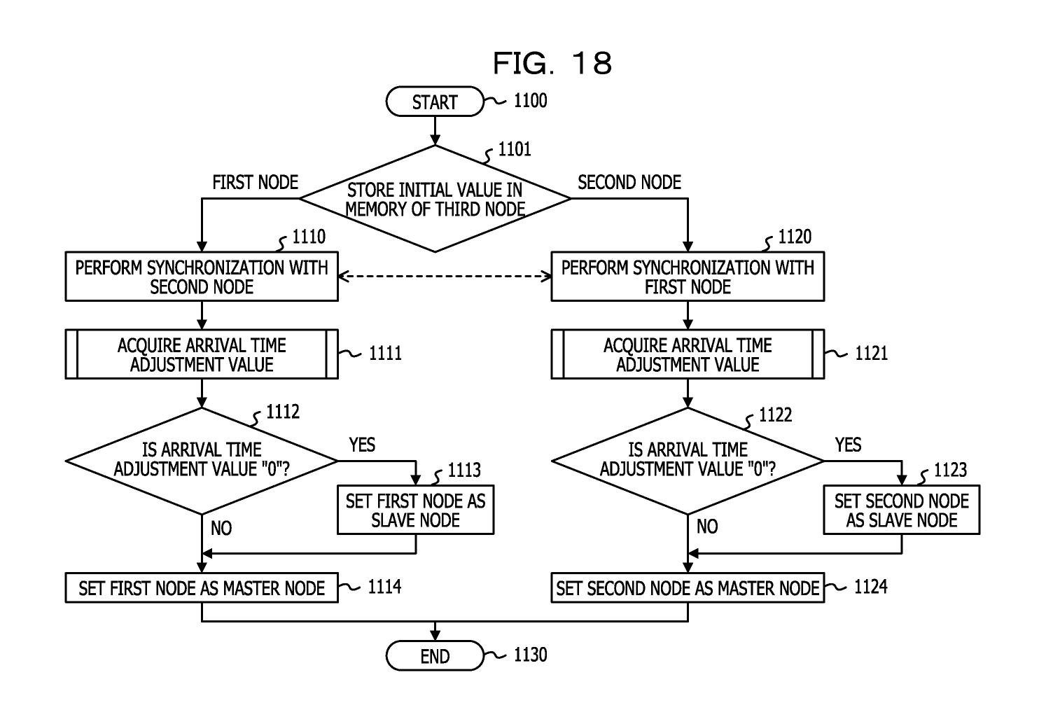

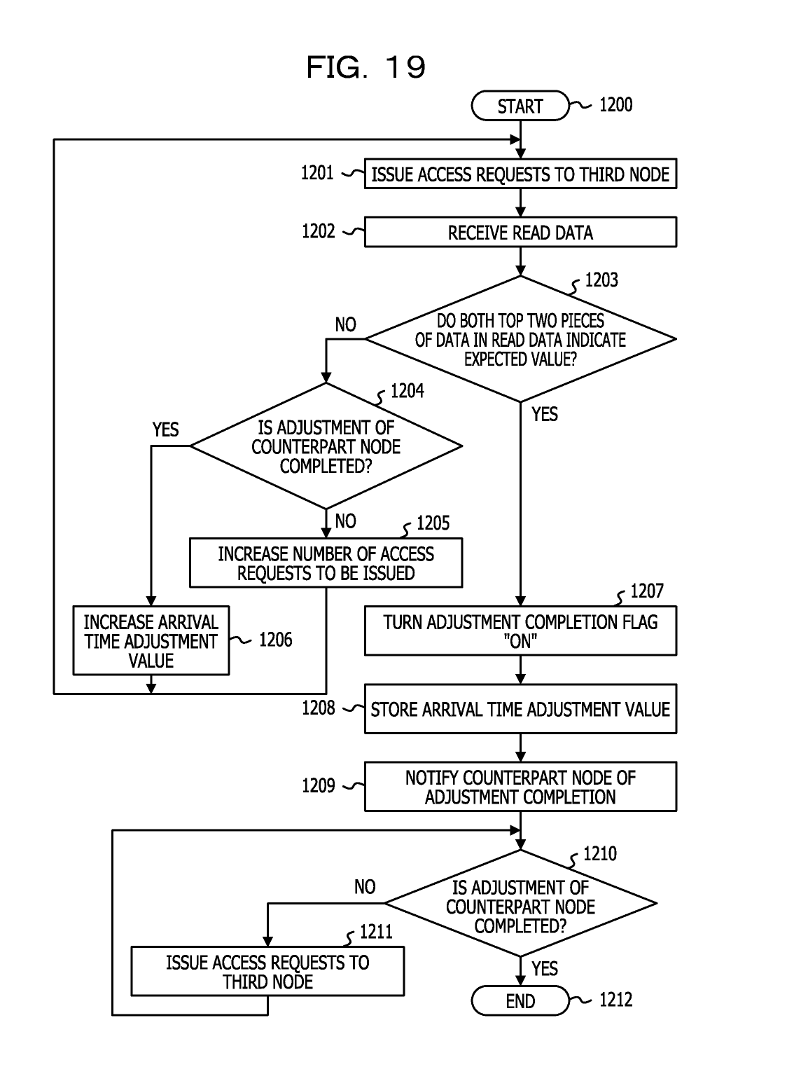

FIG. 18 is a flow chart of the operations for adjusting the times at which access requests arrive at a conflict test target device. The operations in FIG. 18 start in operation 1100. In operation 1101, the setting unit 116 or 216 sets an initial value for the memory 330 of the third node 300. When the object is the first node 100, the process proceeds to operation 1110, and when the object is the second node 200, the process proceeds to operation 1120. In operations 1110 and 1120, each of the synchronization unit 111 of the first node 100 and the synchronization unit 211 of the second node 200 performs a synchronization operation. In operations 1111 and 1121, the processors 150 and 250 adjust the times at which the access requests issued from the respective nodes arrive at the third node 300. The details of operations 1111 and 1121 are described below with reference to another flow chart, which is illustrated in FIG. 19. In operation 1112, the determination unit 112 determines whether or not adjustment is performed for the first node 100 so as to delay the times at which the access requests arrive at the third node 300. When the arrival times are adjusted for the first node 100, the setting unit 116 sets the first node 100 as a master node in operation 1114. When the arrival times are not adjusted for the first node 100, that is, the arrival time adjustment unit 113 does not perform any operations for delaying the issue timings of the access requests, the setting unit 116 sets the first node 100 as a slave node in operation 1113 and the process proceeds to operation 1114. In operation 1122, the determination unit 212 determines whether or not adjustment is performed for the second node 200 so as to delay the times at which the access requests arrive at the third node 300. When the arrival times are adjusted for the second node 200, the setting unit 216 sets the second node 200 as a master node in operation 1124. When the arrival times are not adjusted for the second node 200, that is, the arrival time adjustment unit 213 does not perform any operations for delaying the issue timings of the access requests, the setting unit 216 sets the second node 200 as a slave node in operation 1123 and the process proceeds to operation 1124.

The slave node used herein indicates the node from which a test end signal is issued, which is described below, and the master node used herein indicates the node that receives the test end signal and ends the test. Although FIG. 18 discloses the operations in which the node for which the arrival time adjustment unit adjusts the arrival times is set as a master node, the node for which the arrival times are adjusted by the arrival time adjustment unit may be set as a slave node and the node for which the arrival times are not adjusted may be set as a master node.

FIG. 19 illustrates the details of operations 1111 and 1121 for acquiring the arrival time adjustment value. Since operation 1111 and operation 1121 form the same flow chart, operation 1111 is described herein as a representative example. After operation 1110 in FIG. 18, the access request issue unit 117 issues the access requests 1-1 to 1-4 to the third node 300 successively in operation 1201. In operation 1202, the reception unit 118 receives the data read from the memory 330. In operation 1203, the determination unit 112 determines whether or not both the top two pieces of data in the read data indicate the expected value. When at least one value of the top two pieces of data in the read data does not equal the expected value, in operation 1204, the determination unit 112 determines whether or not the reception unit 118 has received an adjustment completion flag from a counterpart conflict test device, which indicates that the adjustment of the arrival times is completed. When the determination unit 112 determines that the reception unit 118 has not received the adjustment completion flag, in operation 1205, the access request issue unit 117 increases the number of access requests based on atomic commands to be issued and issues the access requests again in operation 1201. When, in operation 1204, the determination unit 112 determines that the reception unit 118 has received the adjustment completion flag, in operation 1206, the arrival time adjustment unit 113 performs adjustment so as to delay the times at which the access requests arrive at the third node 300. After that, the access request issue unit 117 issues the access requests again in operation 1201.

When, in operation 1203, the determination unit 112 determines that both the top two pieces of data in the read data indicate the expected value, the setting unit 116 turns the adjustment completion flag “on” in operation 1207, which indicates that the adjustment of the arrival times is completed. In operation 1208, the setting unit 116 causes the arrival time adjustment value to be stored in the memory 130. In operation 1209, the notification unit 115 notifies the second node 200, which is the counterpart conflict test device, of the adjustment completion flag. In operation 1210, the determination unit 112 determines whether or not the reception unit 118 has received the adjustment completion flag from the counterpart conflict test device, that is, the second node 200. When the determination unit 112 determines that the reception unit 118 has not received the adjustment completion flag yet, the access request issue unit 117 issues the access requests to the third node 300 successively in operation 1211. When, in operation 1210, the determination unit 112 determines that the reception unit 118 has received the adjustment completion flag from the second node 200, the process proceeds to operation 1212 and ends.

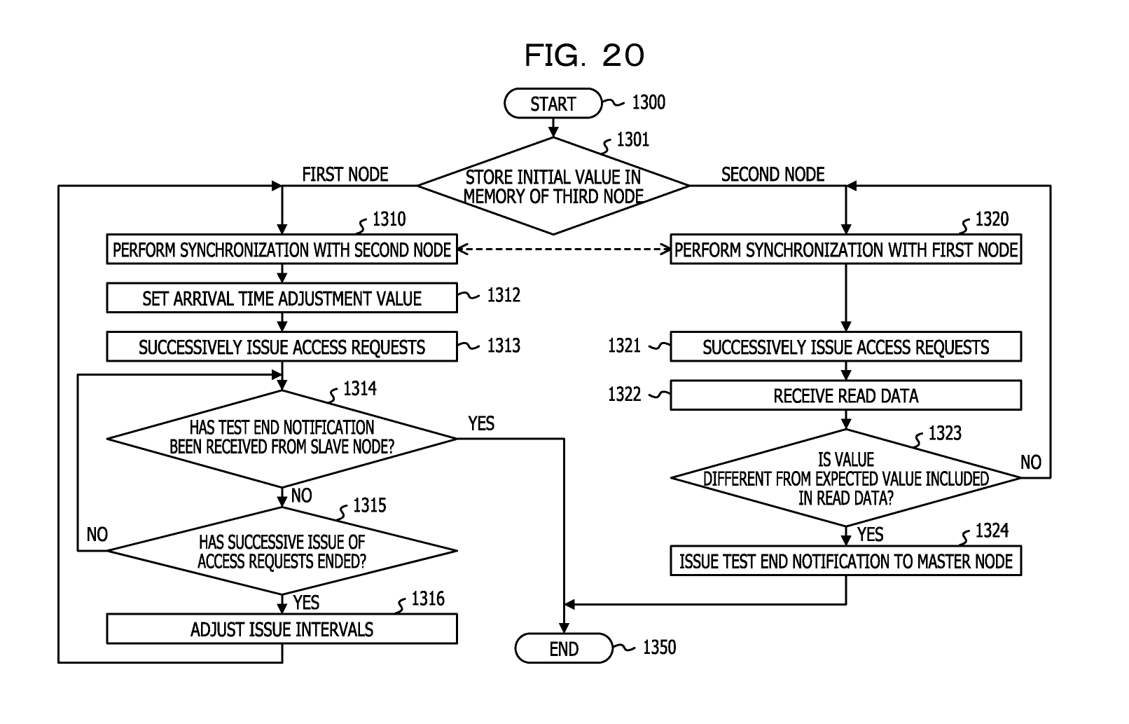

FIG. 20 illustrates the operations for conducting an access request conflict test using the acquired arrival time adjustment value. In the example of FIG. 20, the first node 100 serves as a master node and the second node 200 serves as a slave node. The operations start in operation 1300. In operation 1301, the setting unit 116 causes an initial value to be stored in the memory 330 of the third node 300, which is the conflict test target device. When the object is the first node 100, the process proceeds to operation 1310, and when the object is the second node 200, the process proceeds to operation 1320. In operations 1310 and 1320, the synchronization unit 111 of the first node 100 and the synchronization unit 211 of the second node 200 mutually transmit certain data and repeat synchronization operations until both data may be confirmed.

In operation 1312, the setting unit 116 sets the arrival time adjustment value acquired in operation 1111 of FIG. 18 for the arrival time adjustment unit 113. The access request issue unit 117 issues a plurality of access requests successively in operation 1313, and the access request issue unit 217 issues a plurality of access requests in operation 1321. The access request conflict test is performed when, for example, the lock error signal issued from the lock error signal output unit 311 of the third node 300 is received at the processor 450 of the management device 400.

In operation 1322, the reception unit 218 of the second node 200 receives the read data for the plurality of access requests issued from the second node 200. In operation 1323, the determination unit 212 determines whether or not the received read data includes a value different from the expected value. When the determination unit 212 determines that the read data does not include a value different from the expected value, the process returns to operation 1320. When the determination unit 212 determines that the read data includes a value different from the expected value, the notification unit 215 issues test end notification to the master node in operation 1324 and the process ends in operation 1350.

In operation 1314, the determination unit 112 of the first node 100 as the master node determines whether or not the reception unit 118 has received the test end notification from the second node 200 as the slave node. When the determination unit 112 determines that the reception unit 118 has received the test end notification, the process ends in operation 1350. When the determination unit 112 determines that the reception unit 118 has not received the test end notification, in operation 1315, the determination unit 112 determines whether or not the issue of the access requests has ended. When the determination unit 112 determines that the issue of the access requests has not ended, the process returns to operation 1314. When the determination unit 112 determines that the issue of the access requests has ended, the issue interval adjustment unit 114 adjusts the issue intervals of the access requests in operation 1316. After that, again, the synchronization units 111 and 211 perform the synchronization operations and the access request issue units 117 and 217 issue the access requests successively.

In this manner, the access request conflict test may be conducted by causing a plurality of kinds of overlapping among the access requests issued from the first node 100 and the access requests issued from the second node 200 by adjusting the issue intervals of the access requests. In addition, the test end timing may be determined based on the read data by conducting the access request conflict test while adjusting the issue intervals of the access requests.

Above described is a case in which the first node 100 and the second node 200 operate as the conflict test devices and the third node 300 operates as conflict test target device in the information processor illustrated in FIG. 1. When the first node 100 is set as the conflict test target device, a test may be conducted by setting the second node 200 and the third node 300 as the conflict test devices. When the second node 200 is set as the conflict test target device, a test may be conducted by setting the first node 100 and the third node 300 as the conflict test devices.

When the number of nodes that configure the information processor is four, the following tests are conducted: a test in which a first node and a second node are set as the conflict test devices while a third node is set as the conflict test target device, a test in which the second node and the third node are set as the conflict test devices while a fourth node is set as the conflict test target device, a test in which the third node and the fourth node are set as the conflict test devices while the first node is set as the conflict test target device, and a test in which the fourth node and the first node are set as the conflict test devices while the second node is set as the conflict test target device. When the tests are conducted in this manner, each node is evenly used twice as the conflict test device and once as the conflict test target device. The similar may apply to a case in which the number of nodes that configure the information processor is five or more.

When, for example, the number of nodes that configure the information processor is five, the following tests are conducted: a test in which a first node and a second node are set as the conflict test devices while a third node is set as the conflict test target device, a test in which the first node and the second node are set as the conflict test devices while a fourth node is set as the conflict test target device, a test in which the first node and the second node are set as the conflict test devices while a fifth node is set as the conflict test target device, a test in which the third node and the fourth node are set as conflict test devices while the first node is set as the conflict test target device, and a test in which the third node and the fourth node are set as the conflict test devices while the second node is set as the conflict test target device. In this manner, the tests may be conducted without storing a test program in the fifth node while all the nodes serve as the conflict test target device. The similar may apply to a case in which the number of nodes that configure the information processor is six or more.

Further, a plurality of tests may be conducted concurrently so as to shorten the test time. When, for example, the number of nodes that configure the information processor is six, the following tests may be performed concurrently: a test in which a first node and a second node are set as the conflict test devices while a third node is set as the conflict test target device, and a test in which a fourth node and a fifth node are set as the conflict test devices while a sixth node is set as the conflict test target device. The similar may apply to a case in which the number of nodes that configure the information processor is seven or more.

As an example, the embodiment describes that the data read from the memory in response to an access request is transmitted to the issue source of the access request and stored in the issue source of the access request. However, the read data is not necessarily desired to be transmitted to the node of the issue source of the access request or stored in the node, but may be stored in, for example, the memory 430 of the management device 400 or the memory 330 of the third node 300. In this case, the determination regarding the amount of the delay in a signal passage, which is based on the read data, and the control of the test end may be performed in the management device 400 or the third node 300.

The embodiment further describes, as an example, that the master node receives the test end notification issued from the slave node to end the access request conflict test. However, the management device 400 may receive the test end notification to end the access request conflict test. The access requests that are used are not limited to the access requests based on the atomic commands. The techniques disclosed herein may be implemented by adjusting the arrival times using two different kinds of access requests so that the two kinds of access requests arrive at the test target device alternately.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A test method comprising:
transmitting a plurality of first requests sequentially at first time intervals from a first node to a third node with a memory;
transmitting a plurality of second requests sequentially at the first time intervals from a second node to the third node;
after transmitting the plurality of first requests and transmitting the plurality of second requests, transmitting a plurality of third requests sequentially at the first time intervals from the first node to the third node;
after transmitting the plurality of first requests and transmitting the plurality of second requests, transmitting a plurality of fourth requests sequentially at the first time intervals from the second node to the third node; and
based on data read from the memory for the plurality of first requests and the plurality of second requests, setting times at which the plurality of third requests arrive at the third node so that the plurality of third requests and the plurality of fourth requests arrive at the third node alternately.

2. The test method according to claim 1, wherein
the plurality of first requests and the plurality of third requests are requests to read data stored in the memory, and when the data is a first logical value, to write a second logical value in the memory, and
the plurality of second requests and the plurality of fourth requests are requests to read data stored in the memory, and when the data is the second logical value, to write the first logical value in the memory.

3. The test method according to claim 1, further comprising:
disabling access to the memory after the third node receives the first request until a process for the first request ends; and
disabling access to the memory after the third node receives the second request until a process for the second request ends.

4. The test method according to claim 1, further comprising:
after transmitting the plurality of third requests and after transmitting the plurality of fourth requests, transmitting a plurality of fifth requests sequentially at second time intervals from the first node to the third node, the second time interval being different from the first time interval; and
after transmitting the plurality of third requests and after transmitting the plurality of fourth requests, transmitting a plurality of sixth requests sequentially at the first time intervals from the second node to the third node.

5. The test method according to claim 4, wherein
the fifth request is a request to read data stored in the memory and when the data is a first logical value, to write a second logical value in the memory, and
the sixth request is a request to read data stored in the memory and when the data is the second logical value, to write the first logical value in the memory.

6. The test method according to claim 5, further comprising:
detecting that the read data for the plurality of sixth requests include logical values different from each other; and
terminating the transmitting of the plurality of fifth requests and the plurality of sixth requests.

7. The test method according to claim 3, further comprising:
outputting a lock error signal from the third node when another request is executed while the process for the first request is being performed.

8. The test method according to claim 1, wherein
the first node, the second node, and the third node are mutually coupled through wiring.

9. The test method according to claim 1, wherein
the first node includes a first processor, the second node includes a second processor, the plurality of first requests and the plurality of third requests are issued when the first processor executes a first atomic command, and the plurality of second requests and the plurality of fourth requests are issued when the second processor executes a second atomic command.

10. The test method according to claim 9, wherein
the first atomic command includes
a command to read data stored in the memory,
a command to compare first data included in the first atomic command with first read data read from the memory, and
a command to write second data included in the first atomic command in the memory when the first data and the first read data indicate an identical logical value, and
the second atomic command includes
a command to read data stored in the memory,
a command to compare third data included in the second atomic command with second read data read from the memory, and
a command to write fourth data included in the second atomic command in the memory when the third data and the second read data indicate an identical logical value.

11. An information processing apparatus comprising:
a first memory; and
a first processor coupled to the first memory and configured to
transmit a plurality of first requests sequentially at first time intervals from a first node to a third node with a second memory,
transmit a plurality of second requests sequentially at the first time intervals from a second node to the third node,
after transmitting the plurality of first requests and transmitting the plurality of second requests, transmit a plurality of third requests sequentially at the first time intervals from the first node to the third node,
after transmitting the plurality of first requests and transmitting the plurality of second requests, transmit a plurality of fourth requests sequentially at the first time intervals from the second node to the third node, and
based on data read from the second memory for the plurality of first requests and the plurality of second requests, set times at which the plurality of third requests arrive at the third node so that the plurality of third requests and the plurality of fourth requests arrive at the third node alternately.

12. The information processing apparatus according to claim 11, wherein
the plurality of first requests and the plurality of third requests are requests to read data stored in the second memory, and when the data is a first logical value, to write a second logical value in the second memory, and
the plurality of second requests and the plurality of fourth requests are requests to read data stored in the second memory, and when the data is the second logical value, to write the first logical value in the second memory.

13. The information processing apparatus according to claim 11, wherein the first processor is configured to:
disable access to the second memory after the third node receives the first request until a process for the first request ends, and
disable access to the second memory after the third node receives the second request until a process for the second request ends.

14. The information processing apparatus according to claim 11, wherein the first processor is configured to:
after transmitting the plurality of third requests and after transmitting the plurality of fourth requests, transmit a plurality of fifth requests sequentially at second time intervals from the first node to the third node, the second time interval being different from the first time interval, and
after transmitting the plurality of third requests and after transmitting the plurality of fourth requests, transmit a plurality of sixth requests sequentially at the first time intervals from the second node to the third node.

15. The information processing apparatus according to claim 14, wherein
the fifth request is a request to read data stored in the second memory and when the data is a first logical value, to write a second logical value in the second memory, and
the sixth request is a request to read data stored in the second memory and when the data is the second logical value, to write the first logical value in the second memory.

16. The information processing apparatus according to claim 15, wherein the first processor is configured to:
detect that the read data for the plurality of sixth requests include logical values different from each other, and
terminate the transmitting of the plurality of fifth requests and the plurality of sixth requests.

17. The information processing apparatus according to claim 13, wherein the first processor is configured to:
output a lock error signal from the third node when another request is executed while the process for the first request is being performed.

18. The information processing apparatus according to claim 11, wherein
the first node, the second node, and the third node are mutually coupled through wiring.

19. The information processing apparatus according to claim 11, wherein
the first node includes a first processor, the second node includes a second processor, the plurality of first requests and the plurality of third requests are issued when the first processor executes a first atomic command, and the plurality of second requests and the plurality of fourth requests are issued when the second processor executes a second atomic command.

20. A non-transitory computer-readable storage medium storing a control program that causes an information processing apparatus to execute a process, the process comprising:
transmitting a plurality of first requests sequentially at first time intervals from a first node to a third node with a memory;
transmitting a plurality of second requests sequentially at the first time intervals from a second node to the third node;
after transmitting the plurality of first requests and transmitting the plurality of second requests, transmitting a plurality of third requests sequentially at the first time intervals from the first node to the third node;
after transmitting the plurality of first requests and transmitting the plurality of second requests, transmitting a plurality of fourth requests sequentially at the first time intervals from the second node to the third node; and
based on data read from the memory for the plurality of first requests and the plurality of second requests, setting times at which the plurality of third requests arrive at the third node so that the plurality of third requests and the plurality of fourth requests arrive at the third node alternately.
